(19) United States
(12) Patent Application Publication
(10) Pub. No.: US 2025/0364209 A1
(43) Pub. Date: Nov. 27, 2025

(54) PLASMA PROCESSING APPARATUS AND PLASMA PROCESSING METHOD

(71) Applicant: Hitachi High-Tech Corporation, Minato-ku, Tokyo (JP)

(72) Inventors: Tomohiro SEKINE, Tokyo (JP); Hitoshi TAMURA, Tokyo (JP); Motohiro TANAKA, Tokyo (JP); Tetsip KAWANABE, Tokyo (JP); Makoto SATAKE, Tokyo (JP)

(21) Appl. No.: 18/692,149

(22) PCT Filed: Feb. 15, 2023
(86) PCT No.: PCT/JP2023/005143

§ 371 Date: Mar. 14, 2024

(51) Int. Cl. H01J 37/32; H01L 21/3065

(52) U.S. Cl. CPC H01J 37/32128; H01J 37/32183; H01J 37/3266; H01J 2237/334; H01L 21/3065

(57) ABSTRACT

A uniform plasma processing apparatus and method using a rectangular waveguide which, a circular waveguide which, a circle-rectangle converter which connects the rectangular waveguide and the circular waveguide, a processing chamber, a circularly polarized wave generator disposed inside the circular waveguide, a circularly polarized wave corrector configured to adjust a circularly polarized wave, a control unit configured to adjust an operation of the circularly polarized wave corrector, and an automatic matcher which performs impedance matching in accordance with a reflected electric field, in which an electric field distribution is calculated using the reflected electric field and a scattering matrix S of an electric field propagation region that connects a reflected electric field measurement surface and a surface whose electric field distribution is to be monitored, and an operation of the circularly polarized wave corrector is controlled in accordance with the electric field distribution based on a calculation result.

### TECHNICAL FIELD

The present disclosure relates to a plasma processing apparatus and a plasma processing method, particularly to a plasma processing apparatus that processes a sample by plasma generated by electromagnetic waves propagated through a waveguide and supplied into a processing chamber, and to a plasma processing technique including a circularly polarized wave generator that supplies circularly polarized waves whose polarization planes rotate.

### BACKGROUND ART

In a semiconductor device manufacturing process according to the related art, in order to achieve an increase in a speed and a reduction in power consumption of an element, an increase in the speed and a reduction in the power consumption have been advanced by three-dimensionalization of a device structure in addition to miniaturization thereof. In the future, in order to implement higher performance of a device, it is predicted that the device will shift to a finer and more complicated structure than before. On the other hand, as the structure becomes complicated, the degree of difficulty in the manufacture of the semiconductor device rapidly increases, and an increase in manufacturing cost per chip becomes a problem.

In order to implement the reduction in the manufacturing cost per chip, it is effective to uniformly process a semiconductor wafer and increase the number of chips that can be obtained from one wafer. Based on such a background, the plasma processing apparatus is required to process the semiconductor wafer more uniformly than before.

To meet the above requirement, a technique has been reported as a method for implementing wafer processing uniform in a circumferential direction by improving uniformity of a plasma density distribution in a processing chamber. In the technique, a circularly polarized wave is used as an electromagnetic wave for generating plasma.

PTL 1 and PTL 2 disclose a plasma processing apparatus including a unit for monitoring an axial ratio of a circularly polarized wave in a circular waveguide and an adjustment unit for optimally adjusting the axial ratio again when the axial ratio of the circularly polarized wave deteriorates due to plasma inside a processing chamber or a reflected wave from a dielectric member. Here, the axial ratio of the circularly polarized wave is a name representing a ratio of a minimum value to a maximum value among electric field components of the circularly polarized wave rotating in one cycle. An axial ratio of 1 represents a fully circularly polarized wave, and an axial ratio closer to 0 represents a non-uniform electromagnetic wave.

### CITATION LIST

### Patent Literature

PTL 1: JP2011-77292A
PTL 2: JP2016-96091A

### SUMMARY OF INVENTION

### Technical Problem

In order to improve the processing efficiency of the semiconductor device, it is necessary to make operating time of the plasma processing apparatus as long as possible and to produce the device for a long time. Therefore, it is required to reduce the number of measurement devices mounted on the plasma processing apparatus to the minimum limit and to increase the maintenance cycle as long as possible.

In PTL 1 and PTL 2, in order to control the axial ratio of the circularly polarized wave in the circular waveguide, a plurality of units for f monitoring the circularly polarized wave are provided in the waveguide unit. In this configuration, when measurement accuracy of even one of the monitoring units deteriorates, a circularly polarized wave adjuster does not provide an optimum value, and conversely, non-uniform plasma processing may be performed as compared with the related art. Therefore, regular maintenance of the monitoring unit is required, which may reduce the operating time of the plasma processing apparatus.

The disclosure provides a technique capable of performing uniform plasma processing by controlling an electric field circularity to an optimum value. Other problems and novel features will become apparent from the description of this specification and the accompanying drawings.

### Solution to Problem

One of representative plasma processing apparatuses of the disclosure for solving the above problems includes a waveguide which is coupled to a vacuum container and through which an electric field for generating plasma propagates, a rectangular waveguide which constitutes the waveguide and operates in a lowest-order mode, a circular waveguide which constitutes the waveguide and operates in a lowest-order mode, a circle-rectangle converter which connects the rectangular waveguide and the circular waveguide, a processing chamber which is disposed in the vacuum container below the circular waveguide and in which the plasma is formed by the electric field, a circularly polarized wave generator disposed inside the circular waveguide, a circularly polarized wave corrector configured to adjust a circularly polarized wave inside the circular waveguide, a control unit configured to adjust an operation of the circularly polarized wave corrector, and an automatic matcher which is connected to an end of the rectangular waveguide opposite to the circle-rectangle converter, detects a reflected electric field, and performs impedance matching in accordance with the reflected electric field. An electric field distribution is calculated using the reflected electric field measured by the automatic matcher and a scattering matrix S of an electric field propagation region that connects a reflected electric field measurement surface and a surface whose electric field distribution is to be monitored, and an operation of the circularly polarized wave corrector is controlled in accordance with the electric field distribution based on a calculation result.

### Advantageous Effects of Invention

The disclosure can provide a technique of enabling uniform plasma processing by generating uniform plasma by means of controlling a circularly polarized wave corrector to an optimum setting based on an electric field distribution obtained by using a reflected electric field obtained by an automatic matcher and a scattering matrix S and making a microwave electric field distribution below a circular waveguide portion in a waveguide uniform. That is, the plasma uniform in a circumferential direction is generated by controlling an axial ratio of a circularly polarized wave to an optimum value, and accordingly, uniform plasma processing is implemented. A detector for directly monitoring the axial ratio of the circularly polarized wave inside the circular waveguide portion 202 is not necessary, and mounting is easy.

### BRIEF DESCRIPTION OF DRAWINGS

FIG. 1 is a front cross-sectional view illustrating a schematic overall configuration of a plasma processing apparatus according to an embodiment.

FIG. 2 is a diagram illustrating details of a configuration of a waveguide of the plasma processing apparatus according to the embodiment.

FIG. 3A is a cross-sectional view of the waveguide of the plasma processing apparatus according to the embodiment.

FIG. 3B is a diagram illustrating a circularly polarized wave generator and a circularly polarized wave adjuster according to the embodiment.

FIG. 4 is a diagram illustrating a calculation result of an electric field circularity inside a circular waveguide with respect to an insertion amount of a stub when the reflection coefficient in a tuner |Γ|=0.3 and ∠Γ=60°.

FIG. 5A is a diagram illustrating a calculation result of an electric field circularity inside the circular waveguide with respect to an insertion amount of a stub when a reflection coefficient in a tuner |Γ|=0.2 and ∠Γ=180°.

FIG. 5B is a diagram illustrating a calculation result of an electric field circularity inside the circular waveguide with respect to an insertion amount of a stub when a reflection coefficient in a tuner |Γ|=0.4 and ∠Γ=150°.

FIG. 6 is a control chart for adjusting an insertion amount of a stub of the plasma processing apparatus according to the embodiment.

FIG. 7A is a diagram illustrating actually measured values of a wafer etching amount distribution when a stub is not inserted, using the plasma processing apparatus according to the embodiment.

FIG. 7B is a diagram illustrating actually measured values of a wafer etching amount distribution when the stub is adjusted to an optimum position, using the plasma processing apparatus according to the embodiment.

FIG. 8 is a diagram illustrating a plasma processing method using the plasma processing apparatus according to the embodiment.

FIG. 9 is a diagram illustrating a plasma processing method using a plasma processing apparatus according to a modification.

### DESCRIPTION OF EMBODIMENTS

Hereinafter, embodiments and modifications will be described with reference to the drawings. However, in the following description, the same components are denoted by the same reference signs, and repeated description thereof may be omitted. It should be noted that the drawings may be more schematically illustrated than actual aspects in order to clarify the description, but are merely examples and do not limit the interpretation of the disclosure.

### EMBODIMENT

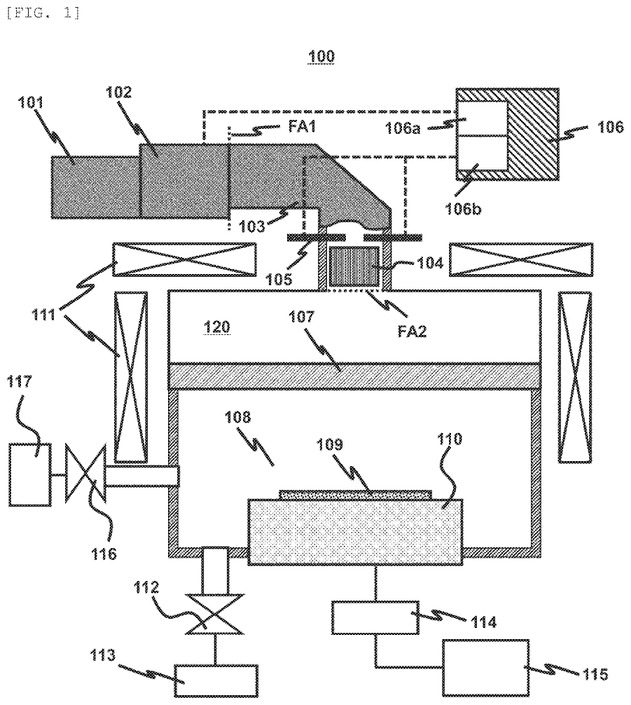

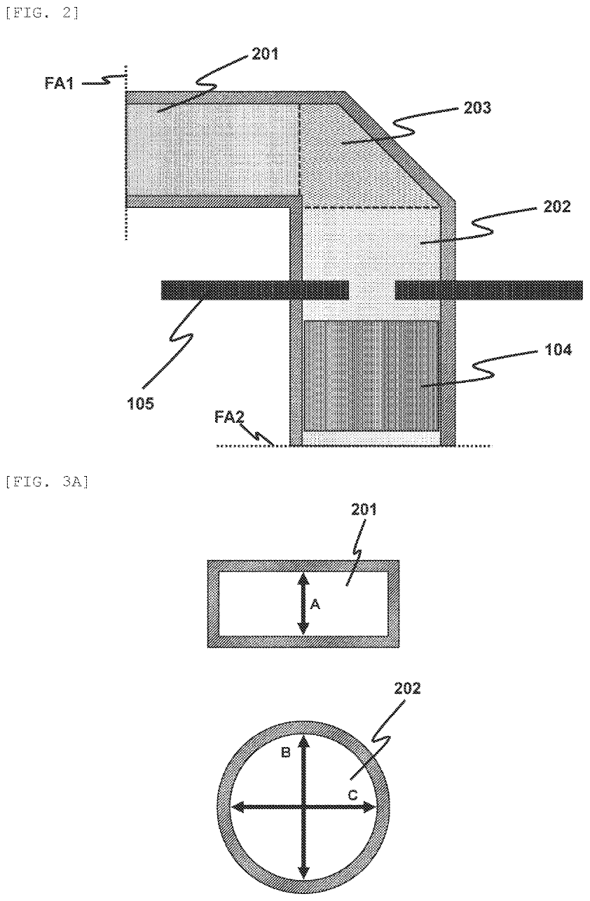

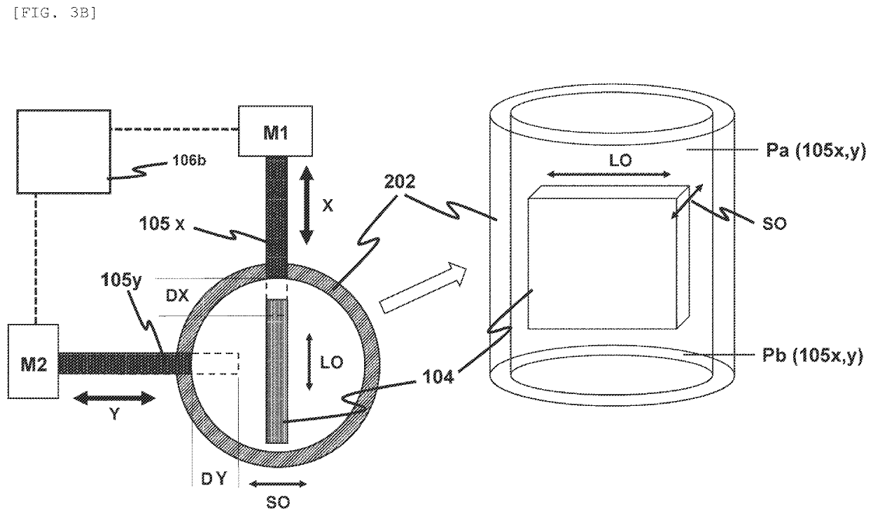

FIG. 1 is a front cross-sectional view illustrating a schematic overall configuration of a plasma processing apparatus according to an embodiment. FIG. 2 is a diagram illustrating details of a configuration of a waveguide of the plasma processing apparatus according to the embodiment. FIG. 3A is a cross-sectional view of the waveguide of the plasma processing apparatus according to the embodiment. FIG. 3B is a diagram illustrating a circularly polarized wave generator and a circularly polarized wave adjuster according to the embodiment.

First, an outline of a configuration of a plasma processing apparatus 100 illustrated in FIG. 1 will be described. The plasma processing apparatus 100 includes a radio frequency power supply 101, a tuner 102, a waveguide 103, a circularly polarized wave generator 104, a circularly polarized wave adjuster 105, a control unit 106, and a processing chamber 108.

The waveguide 103 is coupled to a vacuum container and allows an electric field for generating plasma to propagate. As shown in FIGS. 2 and 3A, the waveguide 103 includes a rectangular waveguide portion 201 which has a rectangular cross section and through which an electromagnetic wave of a lowest-order mode (TM01 mode) propagates, a circular waveguide portion 202 which has a circular cross section and through which an electromagnetic wave of a lowest-order mode (TE11 mode) propagates, and a circle-rectangle conversion portion (circle-rectangle converter) 203 which connects the rectangular waveguide portion 201 and the circular waveguide portion 202.

The radio frequency power supply 101 is a magnetron and supplies an electromagnetic wave, which is a radio frequency power for generating plasma, to the waveguide 103.

The processing chamber 108 is a processing chamber in which a sample (wafer) is subjected to plasma processing, and is disposed in a vacuum container 120 below the circular waveguide portion 202. An electromagnetic wave is supplied from the waveguide 103 into the processing chamber 108 to form plasma.

The circularly polarized wave generator 104 is disposed inside the circular waveguide portion 202 and generates a circularly polarized wave.

The circularly polarized wave adjuster 105 is a circularly polarized wave corrector and is disposed above or below the circularly polarized wave generator 104 to adjust a distribution of circularly polarized waves.

The tuner 102 is an automatic matcher and is connected between the radio frequency power supply 101 and the waveguide 103. The tuner 102 performs impedance matching to prevent the radio frequency power from flowing from the waveguide 103 to the radio frequency power supply 101. The tuner 102 is coupled to the rectangular waveguide portion 201, and calculates an impedance on a load side based on the reflected electromagnetic wave to achieve a state of matching with an impedance on an oscillator side. That is, the tuner 102 is connected to an end of the rectangular waveguide portion 201 opposite to the circle-rectangle conversion portion 203, detects the reflected electric field, and performs impedance matching in accordance with the reflected electric field.

The control unit 106 includes a calculation processing unit 106a and an operation control unit 106b. The calculation processing unit 106a of the control unit 106 is connected to the tuner 102 and calculates the distribution of the circularly polarized waves supplied to the processing chamber 108 from a reflected electromagnetic wave measured by the tuner 102 and a scattering matrix S of the waveguide 103, the circularly polarized wave generator 104, and the circularly polarized wave adjuster 105. The operation control unit 106b of the control unit 106 controls an operation of the circularly polarized wave adjuster 105 and adjusts an insertion amount of the circularly polarized wave adjuster 105 based on the calculation result calculated by the calculation processing unit 106a. For example, when the insertion amount of the circularly polarized wave adjuster 105 is adjusted by a motor, the operation control unit 106b of the control unit 106 is connected to the motor and controls rotation of the motor. When the circularly polarized wave adjuster 105 includes two rod-shaped members (for example, an x stub 105x as a first stub and a y stub 105y (see FIG. 3B) as a second stub) as stubs, the motor includes a first motor M1 that adjusts an insertion amount DX of the x stub 105x and a second motor M2 that adjusts an insertion amount DY of the y stub 105y. The operation control unit 106b of the control unit 106 can individually control the first motor M1 and the second motor M2.

In other words, the control unit 106 calculates the electric field distribution using the reflected electric field measured by the automatic matcher (tuner) 102 and the scattering matrix S of an electric field propagation region connecting a reflected electric field measurement surface FA1 (see FIG. 1) of the automatic matcher (tuner) 102 and a surface FA2 (see FIG. 1) whose electric field distribution is to be monitored, and controls the operation of the circularly polarized wave corrector (circularly polarized wave adjuster) 105 in accordance with the electric field distribution based on the calculation result.

Accordingly, based on the electric field distribution obtained by using the reflected electric field obtained by the automatic matcher 102 and the scattering matrix S, the circularly polarized wave corrector 105 is controlled to an optimum setting, and a microwave electric field distribution in the vacuum container 120 below the circular waveguide portion 202 of the waveguide 103 is made uniform in a circumferential direction to generate plasma uniform in the circumferential direction in the processing chamber 108. Accordingly, uniform plasma processing can be performed on a sample 109 in the processing chamber 108 of the plasma processing apparatus 100.

Further, a configuration of a plasma processing apparatus according to a first embodiment of the disclosure will be described with reference to FIG. 1. As shown in FIG. 1, in the plasma processing apparatus 100 according to the present embodiment, an electromagnetic wave is supplied from the magnetron 101 as a radio frequency power supply to the processing chamber 108 through the waveguide 103 and a dielectric window 107. A solenoid coil 111 is a magnetic field generating mechanism for generating a magnetic field. The electromagnetic wave and electrons that are in cyclotron motion by a static magnetic field generated by the solenoid coil 111 are subjected to electron cyclotron resonance (ECR) to generate plasma. For example, when a microwave having a frequency of 2.45 GHz is used as a plasma source, a static magnetic field of 0.0875 tesla is generated in the processing chamber 108 by the solenoid coil 111. Accordingly, the electron cyclotron resonance phenomenon occurs, and plasma is efficiently generated.

Further, the processing chamber 108 is provided with a base electrode 110 which is a sample stage that allows the sample 109 to be placed. The radio frequency power supply 115 for supplying bias power to the sample 109 to be processed is connected to the base electrode 110 via a matching device 114.

The processing chamber 108 is connected to a gas supply unit 117 via a valve 116, and a gas can be supplied into the processing chamber 108. The supply amount of the gas is controlled according to an opening degree of the valve 116.

The inside of the processing chamber 108 is connected to a pump 113 via a valve 112, and the gas in the processing 117 is chamber 108 supplied from the gas supply unit discharged. An internal pressure of the processing chamber 108 can be adjusted to a constant value by controlling a discharging speed of the gas according to an opening degree of the valve 112.

In the plasma processing apparatus 100, the tuner 102 is provided between the magnetron 101 and the waveguide 103. In the tuner 102, the impedance on a load side is calculated from a measurement result of a reflected wave from the load side, and the impedance on the radio frequency power supply 101 side and the impedance of the load side from the waveguide 103 to the processing chamber 108 are matched, so that the electromagnetic wave is efficiently supplied to the load side.

The control unit 106 may further perform control of a radio frequency power supply of the magnetron 101, control of a magnetic field of the solenoid coil 111, control of opening degrees of the valves 112 and 116, control of the radio frequency power supply 115, and the like.

FIG. 2 is an enlarged view of the waveguide 103. The waveguide 103 includes the rectangular waveguide portion 201 having rectangular cross section, the circular waveguide portion 202 having a circular cross section, and the circle-rectangle conversion portion 203 connecting the rectangular waveguide portion 201 and the circular waveguide portion 202. The rectangular waveguide portion 201 has such a dimension that only an electromagnetic wave of the TM01 mode, which is the lowest-order mode, can propagate, and the circular waveguide portion 202 has such a dimension that only an electromagnetic wave of the TE11 mode, which is the lowest-order mode, can propagate.

In FIG. 2, one end portion of the rectangular waveguide portion 201 is connected to the automatic matcher (tuner) 102. The reflected electric field measurement surface FA1 of the automatic matcher (tuner) 102 is set between the automatic matcher (tuner) 102 and the one end portion of the rectangular waveguide portion 201 in this example. The other end portion of the rectangular waveguide portion 201 is connected to one end of the circle-rectangle conversion portion 203. The other end of the circle-rectangle conversion portion 203 is connected to one end of the circular waveguide portion 202, and the other end of the circular waveguide portion 202 is connected to the vacuum container 120. The surface FA2 whose electric field distribution is to be monitored is set between the other end of the circular waveguide portion 202 and the vacuum container 120 in this example.

The circularly polarized wave generator 104 that generates a circularly polarized wave is disposed in the circular waveguide portion 202.

Here, the circularly polarized wave will be briefly described. When an electric field vector of the electromagnetic wave is defined on a central axis of the circular waveguide, a plane including a traveling direction of the electromagnetic wave and the electric field vector is referred to as a polarization plane. An electromagnetic wave in which the polarization plane rotates temporally and a trajectory of the electric field vector is a perfect circle is defined as a circularly polarized wave. On the other hand, an electromagnetic wave whose polarization plane does not temporally rotate is referred to as a linearly polarized wave. The circularly polarized wave can be generated by superimposing two linearly polarized waves having polarization planes orthogonal to each other and having phases different from each other by 90°.

As a circularly polarized wave generation unit using the above-described circularly polarized wave generating mechanism, various ones are known in the related art, and even in the disclosure, any one can be used as long as a condition that a surface of the waveguide 103 in contact with the dielectric window 107 which is a quartz window is circular is satisfied. In particular, in the plasma processing apparatus 100 of FIG. 1, a plate-shaped member 104 made of a dielectric is introduced into the waveguide 103 as a circularly polarized wave generator such that a surface thereof is parallel to the waveguide 103. In this configuration, regarding a component of the linearly polarized wave introduced from an upper portion of the waveguide 103, which is in a direction parallel to a longitudinal direction LO (see FIG. 3B) of the circularly polarized wave generator 104, a wavelength is reduced by a difference in the dielectric constant from the vacuum. On the other hand, regarding a component in a direction parallel to a short-side direction SO (see FIG. 3B) of the circularly polarized wave generator 104, a wavelength thereof is not reduced. Therefore, by optimally adjusting a length of the circularly polarized wave generator 104 in a direction parallel to the waveguide 103, a phase difference of exactly 90° can be generated between the component of the linearly polarized wave in the direction parallel to the longitudinal direction LO of the circularly polarized wave generator 104 and the component of the linearly polarized wave in the direction parallel to the short-side direction SO of the circularly polarized wave generator 104, and the circularly polarized wave can be generated by combining the components below the circularly polarized wave generator 104.

As a circularly polarized wave correction unit for controlling the axial ratio of the circularly polarized wave, various units are known in the related art, and any one can be used in the disclosure. As illustrated in FIGS. 2 and 3B, in the present embodiment, a method is used in which two rod-shaped members 105 called stubs serving as the circularly polarized wave corrector 105 are attached to the circular waveguide portion 202 in a manner of being perpendicular to the circular waveguide portion 202, and the insertion amounts (DX, DY) thereof are respectively controlled to adjust the electric field circularity of the circularly polarized wave. The circularly polarized wave corrector 105 may be disposed at a first position Pa above the circularly polarized wave generator 104 or a second position Pb below the circularly polarized wave generator 104.

As illustrated in FIG. 3B, in this example, one of the two stubs 105 serving as the circularly polarized wave correctors is disposed parallel to the longitudinal direction LO of the circularly polarized wave generator 104. The stub 105 is hereinafter referred to as an x stub (105x, first stub). In addition, in the two stubs 105 which are the circularly polarized wave correctors, the other stub 105 is disposed parallel to the short-side direction So of the circularly polarized wave generator 104. The stub 105 is hereinafter referred to as a y stub (105y, second stub). The arrangement direction of the x stub (105x) and the y stub (105y) may be set regardless of the longitudinal direction LO and the short-side direction SO of the circularly polarized wave generator 104. That is, a longitudinal direction of the x stub (105x) is provided along the first direction X, and the x stub (105x) is set in a manner of being insertable into the circular waveguide portion 202 along the first direction X so that the insertion amount DX is controlled by the first motor M1. On the other hand, a longitudinal direction of the y stub (105y) is provided along a second direction Y intersecting or perpendicular to the first direction X, and is set in a manner of being insertable into the circular waveguide portion 202 along the second direction Y so that the insertion amount DX thereof is controlled by the second motor M2. That is, the insertion amounts (DX, DY) of the stubs 105 (105x, 105y) are adjustable.

A control method of the stubs 105 will be described. In the disclosure, the electric field circularity inside the circular waveguide portion 202 is calculated, and the insertion amounts (DX and DY) of the stubs 105 (105x and 105y) are controlled so that the calculated electric field circularity is improved.

A method for calculating the electric field circularity will be described with reference to FIG. 3A. Only the electromagnetic wave of the TM01 mode propagates inside the rectangular waveguide portion 201, and thus an electric field component on a surface connected to the tuner 102 (corresponding to the reflected electric field measurement surface FA1) is limited to a unidirectional component in an A axis. In addition, only the electromagnetic wave of the TE11 mode propagates inside the circular waveguide portion 202, and thus an electric field vector can be described by two-directional components when considering two axes orthogonal to each other, that is, a B axis and a C axis.

A connection surface (FA1) of the rectangular waveguide portion 201 with the tuner 102 is defined as a port 1, and a B-axis component and a C-axis component are defined as a port 2 and a port 3, respectively, at a lower end (corresponding to the surface FA2 whose electric field distribution is to be monitored) of the circular waveguide portion 202. At this time, assuming that aᵢ represents an incident wave and bᵢ represents a reflected wave (here, i represents the port number: 1, 2, 3) at each of the port 1, the port 2, and the port 3, the relationship therebetween can be described as shown in (Formula 1) using the scattering matrix S.

$$[ \begin{matrix}{b}_{1} \\ {b}_{2} \\ {b}_{3}\end{matrix} ] = [ \begin{matrix}{S}_{11} & {S}_{12} & {S}_{13} \\ {S}_{21} & {S}_{22} & {S}_{23} \\ {S}_{31} & {S}_{32} & {S}_{33}\end{matrix} ] [ \begin{matrix}{a}_{1} \\ {a}_{2} \\ {a}_{3}\end{matrix} ] \qquad ( Formula 1 )$$

Here, the scattering matrix S refers to a matrix generally describing a relationship between a starting state and a final state, and particularly in the disclosure, is a matrix describing a relationship between an incident wave and a reflected wave in a port. That is, the scattering matrix S is a scattering matrix of an electric field propagation region connecting the reflected electric field measurement surface FA1 of the tuner 102 and the surface FA2 whose electric field distribution is to be monitored.

A reflection coefficient Γ of an electromagnetic wave measured by the tuner 102 corresponds to a ratio of a reflected wave to an incident wave at the port 1. Therefore, a relationship between an incident wave aᵢ and a reflected wave b₁ can be described as in (Formula 2) using the reflection coefficient T.

$${B}_{1} = \begin{matrix}Γ & {a}_{1}\end{matrix} \qquad ( Formula 2 )$$

Using a reflection coefficient R at the lower end of the circular waveguide portion 202, a relationship between an incident wave a₂ and a reflected wave by and a relationship between an incident wave a₃ and a reflected wave b₃ can be expressed by (Formula 3) and (Formula 4), respectively.

$${A}_{2} = R {b}_{2} \qquad ( Formula 3 )$$

$${A}_{3} = R {b}_{3} \qquad ( Formula 4 )$$

Here, the reflection coefficient R of magnetized plasma is a tensor. Here, when the reflection coefficient R is expressed by a tensor, the number of unknowns increases with respect to the number of the equations, and the simultaneous equations cannot be solved. Therefore, in the disclosure, the reflection coefficient R in the magnetized plasma is approximated by a scalar value.

(Formula 5) is obtained by setting the incident wave at the port 1 as 1 and using (Formula 1) to (Formula 4).

$$[ \begin{matrix}Γ \\ \frac{{a}_{2}}{R} \\ \frac{{a}_{3}}{R}\end{matrix} ] = [ \begin{matrix}{S}_{11} & {S}_{12} & {S}_{13} \\ {S}_{21} & {S}_{22} & {S}_{23} \\ {S}_{31} & {S}_{32} & {S}_{33}\end{matrix} ] [ \begin{matrix}1 \\ {a}_{2} \\ {a}_{3}\end{matrix} ] \qquad ( Formula 5 )$$

(Formula 5) is a simultaneous equation of three equations for three unknowns, a₂, a₃, and R. Therefore, by solving (Formula 5), the electric field circularity inside the circular waveguide portion 202 can be determined from the reflection coefficient Γ of the electromagnetic wave in the tuner 102.

Thereafter, the insertion amounts (DX, DY) of the stubs 105 (105x, 105y) for improving the electric field circularity inside the circular waveguide portion 202 are calculated by the control unit 106, and the insertion amounts (DX, DY) of the stubs 105 (105x, 105y) are adjusted based on the result.

In this case, when the insertion amounts (DX, DY) of the stubs 105 (105x, 105y) are changed, a scattering matrix S of the waveguide 103 and the reflection coefficient Γ are changed. Therefore, in the disclosure, it is preferable that the insertion amounts (DX, DY) of the stubs 105 (105x, 105y) are gradually changed, and the calculations of (Formula 1) to (Formula 4) and (Formula 5) are executed again using the scattering coefficient S changed each time, to calculate the electric field circularity.

A target value of the electric field circularity can be achieved by repeating the above operation of the stubs 105 (105x, 105y) until the calculated value of the electric field circularity is equal to or greater than a desired value.

The scattering matrix S can be acquired by simulation or measurement in advance. The scattering matrix S changes depending on the configuration of the waveguide 103, and is determined when a configuration of the waveguide 103 is determined. The scattering matrix S is preferably stored in a database stored in a storage area of the control unit 106.

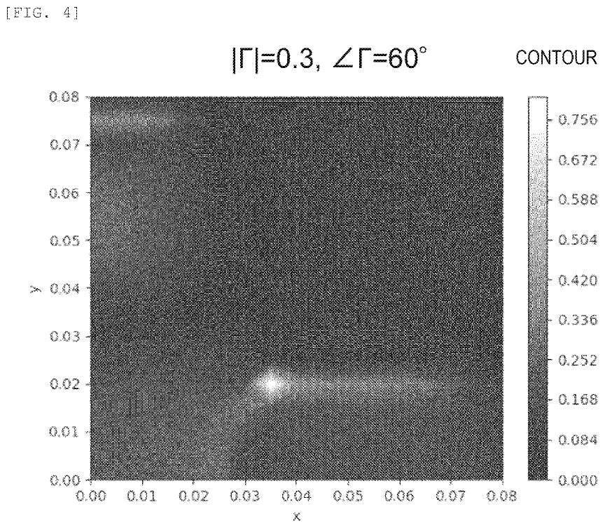

FIG. 4 is a diagram illustrating a calculation result of electric field circularity inside the circular waveguide portion 202 with respect to the insertion amounts (DX, DY) of the stubs when the reflection coefficient in the tuner |Γ|=0.3 and ∠Γ=60°. FIG. 4 illustrates values obtained by acquiring the scattering matrix S using the simulation of a finite element method and calculating the electric field circularity with respect to the insertion amounts (DX, DY) of the respective two stubs 105 (105x, 105y). In FIG. 4, a horizontal axis x indicates the insertion amount DX of the x stub (105x), a vertical axis y indicates the insertion amount DY of the y stub (105y), and a contour (equal line) indicates the electric field circularity. The stub insertion amount is shown in mm, and the maximum insertion amount of both x and y is 80 mm. FIG. 4 illustrates a result of the electric field circularity when the magnitude |Γ| of the reflection coefficient of the electromagnetic wave in the tuner 102 is 0.3 and the phase ∠Γ thereof is 60°.

It can be seen from FIG. 4 that the electric field circularity is the highest at a point where the x stub (105x) is inserted by 35 mm and the y stub (105y) is inserted by 20 mm.

In this case, as described above, when the insertion amounts (DX, DY) of the stubs 105 are changed, the values of the scattering matrix S and the reflection coefficient I of the waveguide 103 are changed. Therefore, when the stubs 105 are suddenly changed to the optimum stub insertion amount derived from the reflection coefficient Γ at a time point when the stubs 105 are not inserted, the optimum insertion amount of the stub may not be achieved.

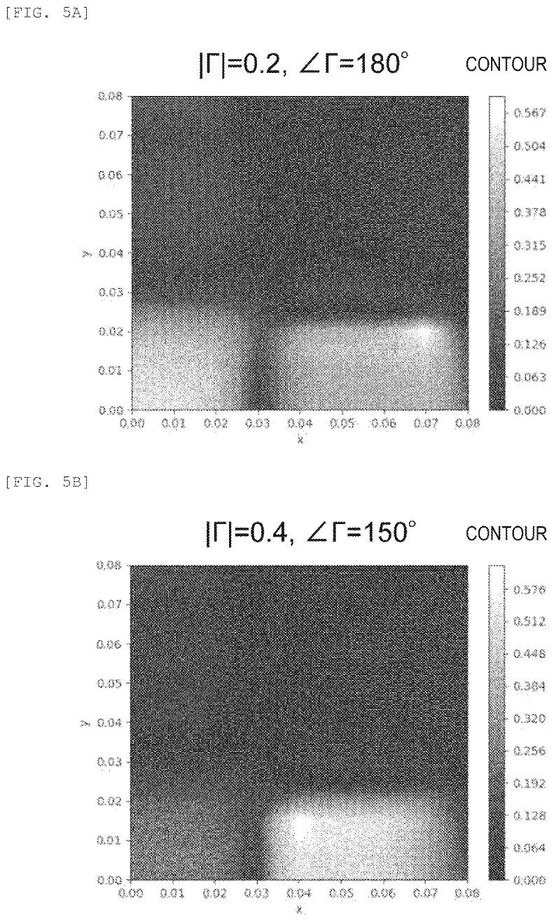

Description will be made using actual measurement results. FIG. 5A is a diagram illustrating a calculation result of electric field circularity inside the circular waveguide portion 202 with respect to a stub insertion amount when a reflection coefficient in a tuner |Γ|=0.2 and ∠Γ=180°. FIG. 5B is a diagram illustrating a calculation result of electric field circularity inside the circular waveguide portion 202 with respect to a stub insertion amount when a reflection coefficient in the tuner |Γ|=0.4 and ∠Γ=150°. In FIGS. 5A and 5B, the stub insertion amount is shown in mm.

FIG. 5A shows a relationship between the insertion amounts (DX, DY) of the stubs and the electric field circularity when the stubs 105 are not inserted (|Γ|=0.2, ∠Γ=) 180°. It can be seen from FIG. 5A that the optimum electric field circularity is achieved by inserting the x stub (105x) by 70 mm and the y stub (105y) by 20 mm. However, when the x stub (105x) is actually inserted by 70 mm and the y stub (105y) is actually inserted by 20 mm, the reflection coefficient Γ of the tuner 102 changes to |Γ|=0.4 and ∠Γ=150° due to the influence of the electric field reflection at the stubs 105. The relationship between the stub insertion amount and the electric field circularity in this case is shown in FIG. 5B. At this time, the optimum stub insertion amount of the x stub is 40 mm, and the optimum stub insertion amount of the y stub is 15 mm. It can be seen that the optimum stub insertion amount is not achieved.

As described above, the reflection coefficient Γ of the electromagnetic wave in the tuner 102 and the insertion amounts (DX, DY) of the stubs are not independent variables but influence each other. Therefore, even if the insertion amounts of the stubs are changed to the optimum value determined from the reflection coefficient Γ at a time point when the stubs 105 (105x, 105y) are not inserted, the optimum electric field circularity cannot be achieved, and a control mechanism is required.

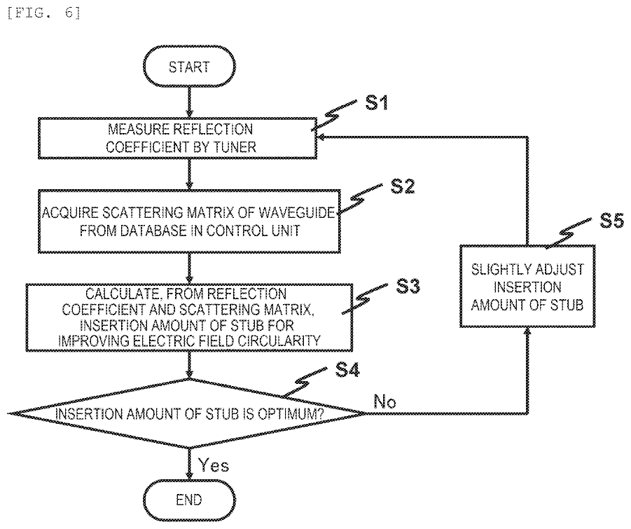

FIG. 6 is a control chart for adjusting the insertion amount of the stub of the plasma processing apparatus according to the embodiment. A control chart of the insertion amount of the stub based on the measurement value of the reflection coefficient Γ in the tuner 102 will be described with reference to FIG. 6.

### (Step S1)

First, the control unit 106 acquires a measurement value of the reflection coefficient Γ of the reflected electromagnetic wave measured by the tuner 102.

### (Step S2)

The control unit 106 acquires the scattering matrix S of the waveguide 103 from the database of the control unit 106.

### (Step S3)

The control unit 106 determines the electric field circularity from the acquired reflection coefficient Γ and the acquired scattering matrix S. Then, the control unit 106 calculates the insertion amounts (DX, DY) of the stubs 105 for improving the electric field circularity and controls the motors M1 and M2 based on the calculation result to adjust the insertion amounts (DX, DY) of the stubs 105. That is, the control unit 106 calculates the insertion amounts (DX, DY) of the stubs for improving the electric field circularity, and predicts the insertion amounts of the stubs.

### (Step S4)

The control unit 106 determines whether the insertion amounts (DX, DY) of the stubs are most appropriate. When the insertion amounts (DX, DY) of the stubs are optimum (Yes), the control chart is ended. On the other hand, when the insertion amounts (DX, DY) of the stubs are not optimum (No), the processing proceeds to step S5.

### (Step S5)

Next, the control unit 106 finely adjusts the insertion amount of the stub by controlling the insertion amounts (DX, DY) of the stubs 105 (that is, the first motor M1 and the second motor M2 are controlled by the control unit 106). Then, steps S1 to S3 are repeated again. At this time, the control unit 106 gradually changes the control amounts which are the insertion amounts (DX, DY) of the stubs, and updates the optimum insertion amounts of the stubs with reference to the reflection coefficient Γ each time.

The above operations (S1 to S5) are repeatedly performed, and the control chart is ended at a time point when the current (DX, DY) of the stubs 105 coincide with the optimum stub insertion amounts.

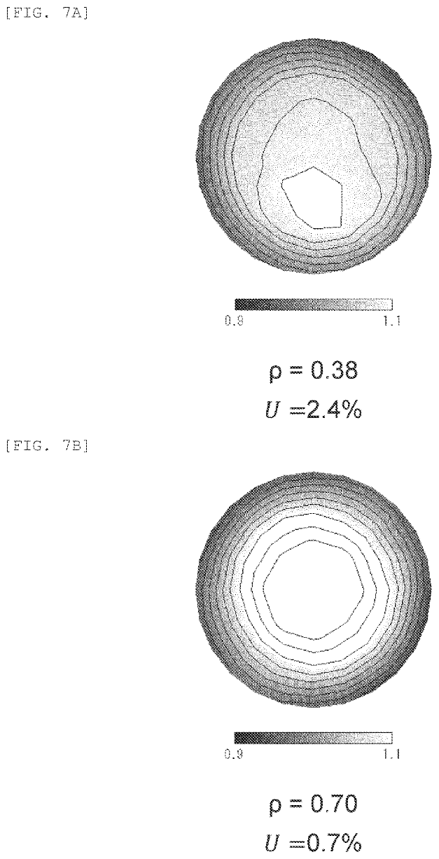

A wafer processing result when the insertion amount of the stub is actually adjusted by using the calculation result of the electric field circularity will be described with reference to FIGS. 7A and 7B. FIG. 7A is a diagram illustrating actually measured values of a wafer etching amount distribution when a stub is not inserted, using the plasma processing apparatus according to the embodiment. FIG. 7B is a diagram illustrating actually measured values of the wafer etching amount distribution when the stub is adjusted to an optimum position, using the plasma processing apparatus according to the embodiment.

FIGS. 7A and 7B illustrate experimental results using a microwave plasma etching apparatus for etching a wafer of 30 mm as a material of a semiconductor device by supplying 2.45 GHz microwaves to a vacuum processing chamber and using plasma generated by electron cyclotron resonance. The contour represents the amount of etching on a wafer surface over a certain time period. Further, lines having the same etching amount are indicated by contour lines.

FIG. 7A shows an etching result when the stubs are not inserted. In a state in which the stubs are not inserted, a value of the electric field circularity calculated from the reflection coefficient Γ of the tuner is 0.38. Further, it can be seen from the etching results that a peak of the etching amount is deviated from a center of the wafer and the distribution is non-uniform in the circumferential direction of the wafer.

Here, as a value for quantitatively evaluating the distribution of the etching amount, the uniformity U of the etching amount at a wafer radius of 100 mm is defined by (Formula 6).

U=((maximum value−minimum value)/(maximum value+minimum value))×100% (Formula6)

As the value of the uniformity U is increased, the distribution of the etching amount in the circumferential direction is non-uniform. As the value is close to 0, the distribution of the etching amount is uniform.

When the above (Formula 6) is used, the uniformity U of the etching amount in FIG. 7A is expressed as U=2.4%.

Next, FIG. 7B illustrates a result when the stub insertion amount is adjusted using the method proposed in the disclosure and the distribution of the etching amount is acquired. At this time, the insertion amount of the x stub is 70 mm, and the insertion amount of the y stub is 15 mm. The electric field circularity determined from the reflection coefficient Γ measured by the tuner 102 is 0.59. The value of the electric field circularity is improved as compared with the value of the electric field circularity before control of 0.38. The calculated uniformity U of the etching amount defined by (Formula 6) is expressed as U=0.7%. Accordingly, as a result of controlling the stubs 105 by the method proposed in the disclosure, it can be seen that the distribution of the etching amounts is improved from 2.4% to 0.7%.

As described above, by controlling the stubs 105 to the optimum setting based on the electric field distribution obtained by using the reflected electric field obtained by the tuner 102 and the scattering matrix S, the microwave electric field distribution inside the circular waveguide portion 202 of the waveguide 103 can be made uniform. Therefore, the microwave electric field distribution in the processing chamber 108 below the waveguide 103 can be made uniform. Accordingly, uniform plasma can be generated in the processing chamber 108, and thus uniform plasma processing can be performed on the wafer in the plasma processing apparatus 100. In particular, the plasma uniform in the circumferential direction with respect to the center of the wafer can be generated in the processing chamber 108, and thus the plasma processing uniform in the circumferential direction of the wafer can be performed in the plasma processing apparatus 100.

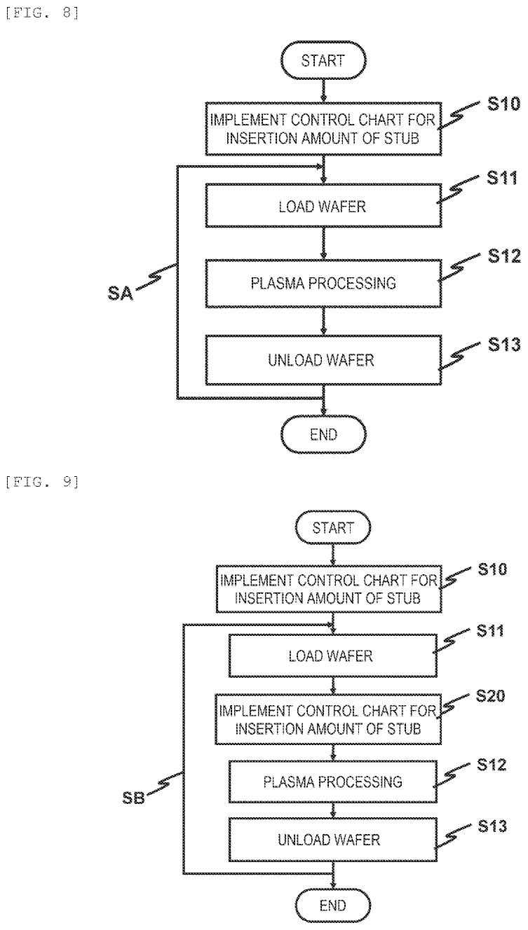

Next, a plasma processing method for a wafer (semiconductor wafer) using the plasma processing apparatus 100 will be described with reference to FIG. 8. FIG. 8 is a diagram illustrating the plasma processing method using the plasma processing apparatus 100 according to the embodiment.

### (Step S10)

First, in the plasma processing apparatus 100, the control chart of the stub insertion amount described in FIG. 6 is performed. Accordingly, the stub 105 is controlled to an optimal setting so that uniform plasma can be generated in the processing chamber 108. Step S10 is also referred to as a first step.

### (Step S11)

The sample 109 which is a semiconductor wafer is loaded into the processing chamber 108, and the sample 109 is placed on the base electrode 110 which is a sample stage. Step S11 is also referred to as a second step.

### (Step S12)

Next, plasma is generated inside the processing chamber 108, and the sample 109 is processed by the plasma. Examples of the plasma processing include etching and film formation. In the case of the etching, a gas for etching is supplied into the processing chamber 108 from the gas supply unit 117. In the film formation, a gas for film formation is supplied from the gas supply unit 117 into the processing chamber 108. As the gas for etching and the gas for film formation, known gases can be used, and thus detailed description thereof will be omitted. Step S12 is also referred to as a third step.

### (Step S13)

Next, the sample 109 which is a semiconductor wafer is unloaded from the inside of the processing chamber 108. Step S13 is also referred to as a fourth step.

Accordingly, the plasma processing method in the plasma processing on the semiconductor wafer 109 is completed. Accordingly, in the processing chamber 108 of the plasma processing apparatus 100 in which the microwave electric field distribution is made uniform, the semiconductor wafer 109 is processed by plasma, so that uniform plasma processing can be performed. In particular, uniform plasma processing can be performed in the circumferential direction with respect to the center of the semiconductor wafer 109.

As shown in step SA of FIG. 8, after step S10 is performed, the plasma processing of the plurality of semiconductor wafers 109 can be performed by repeating steps S11 to S13. That is, the scattering matrix S is determined when the configuration of the waveguide 103 of the plasma processing apparatus 100 is determined, and thus the uniform plasma processing can be performed on the semiconductor wafer 109 by performing step S10 once.

### (Modification)

FIG. 9 is a diagram illustrating a plasma processing method using a plasma processing apparatus according to a modification. The plasma processing method in the modification illustrated in FIG. 9 is different from the plasma processing method in the embodiment illustrated in FIG. 8 in that step S20 (step S20 is also referred to as a fifth step) in which the control chart of the insertion amount of the stub illustrated in FIG. 6 is performed is added between step S11 (second step) and step S12 (third step). Similar to step S10, step S20 is a control chart step of the stub insertion amount.

Therefore, as shown in step SB, when the plasma processing is performed on the plurality of semiconductor wafers 109 by repeating steps S11, S20, S12, and S13, step S20 is performed every time the plasma processing is repeated. As described above, step S20 is performed every time the processing is repeated, and thus the microwave electric field distribution in the circular waveguide portion 202 of the waveguide 103 can be made more uniform. Therefore, the microwave electric field distribution inside the processing chamber 108 below the waveguide 103 can be made more uniform. Accordingly, more uniform plasma can be generated in the processing chamber 108, and thus more uniform plasma processing can be performed on the semiconductor wafer 109 in the plasma processing apparatus 100.

Although the disclosure specifically described above based on embodiments, it is needless to say that the disclosure is not limited to the above-described embodiments and can be variously changed.

### REFERENCE SIGNS LIST

100: plasma processing apparatus
102: tuner (automatic matcher)
103: waveguide
104: circularly polarized wave generator
105: circularly polarized wave adjuster (circularly polarized wave corrector)
106: control unit
108: processing chamber
109: sample (semiconductor wafer)
110: base electrode (sample stage)

1-8. (canceled)

9. A plasma processing apparatus comprising:
a processing chamber in which a sample is treated with plasma;
a radio frequency power supply that supplies radio frequency power for generating plasma to the processing chamber via a circular waveguide;
a circularly polarized wave generator located inside the circular waveguide;
a matcher that performs impedance matching based on the reflected radio frequency power;
a sample stage on which the sample is placed;
a circularly polarized wave adjuster that adjusts the circularly polarized waves inside the circular waveguide; and
a control unit that controls the circularly polarized wave adjuster based on the electric field distribution calculated using an electric field due to the reflected radio frequency power and a scattering matrix S of an electric field propagation region connecting a reflected electric field measurement surface and a surface whose an electric field distribution is to be monitored,
wherein the electric field due to the reflected radio frequency power is the electric field measured by the matcher.

10. The plasma processing apparatus according to claim 9, further comprising:
a magnetic field generating mechanism that forms a magnetic field.

11. The plasma processing apparatus according to claim 9,
wherein the control unit controls the circularly polarized wave adjuster and then controls the circularly polarized wave adjuster based on the electric field distribution calculated using the electric field due to the reflected radio frequency power and the scattering matrix S of the electric field propagation region connecting a reflected electric field measurement surface and a surface whose an electric field distribution is to be monitored.

12. The plasma processing apparatus according to claim 11,
wherein the circularly polarized wave adjuster includes a first stub inserted into the circular waveguide along a first direction and a second stub inserted into the circular waveguide along a second direction that intersects the first direction, and
wherein the control unit independently controls an insertion amount of the first stub and the second stub based on the calculated electric field distribution.

13. A plasma processing method using a plasma processing apparatus comprising a processing chamber in which a sample is treated with plasma; a radio frequency power supply that supplies radio frequency power for generating plasma to the processing chamber via a circular waveguide; a circularly polarized wave generator located inside the circular waveguide; a matcher that performs impedance matching based on the reflected radio frequency power; a sample stage on which the sample is placed; and a circularly polarized wave adjuster that adjusts the circularly polarized waves inside the circular waveguide, the plasma processing method comprising:
a step of controlling the circularly polarized wave adjuster based on the electric field distribution calculated using an electric field due to the reflected radio frequency power and a scattering matrix S of an electric field propagation region connecting a reflected electric field measurement surface and a surface whose an electric field distribution is to be monitored,
wherein the electric field due to the reflected radio frequency power is the electric field measured by the matcher.

14. The plasma processing method according to claim 13,
wherein the step controls the circularly polarized wave adjuster and then controls the circularly polarized wave adjuster based on the electric field distribution calculated using the electric field due to the reflected radio frequency power and the scattering matrix S of the electric field propagation region connecting a reflected electric field measurement surface and a surface whose an electric field distribution is to be monitored.

15. The plasma processing method according to claim 14,
wherein the circularly polarized wave adjuster includes a first stub inserted into the circular waveguide along a first direction and a second stub inserted into the circular waveguide along a second direction that intersects the first direction, and
wherein the step independently controls an insertion amount of the first stub and the second stub based on the calculated electric field distribution.

16. The plasma processing method according to claim 15,
wherein the step is performed between a time the sample is transported to the processing chamber and a time the sample is plasma treated.
